(19) United States
(12) Patent Application Publication
(10) Pub. No.: US 2025/0298175 A1
(43) Pub. Date: Sep. 25, 2025

(54) EUV COLLECTOR

(71) Applicant: Carl Zeiss SMT GmbH, Oberkochen (DE)

(72) Inventor: Valentin Jonatan BOLSINGER, Aalen (DE)

(21) Appl. No.: 19/233,423

(22) Filed: Jun. 10, 2025

Related U.S. Application Data
(63) Continuation of application No. PCT/EP2023/085374, filed on Dec. 12, 2023.

(30) Foreign Application Priority Data
Dec. 19, 2022 (DE) 10 2022 213 822.8

(51) Int. Cl. G02B 5/18; G02B 19/00; G03F 7/00

(52) U.S. Cl. CPC G02B 5/1814; G02B 5/1838; G02B 19/0019; G03F 7/70033; G03F 7/70158; G03F 7/70175; G03F 7/702

(57) ABSTRACT

An EUV collector is used to collect EUV used light eminating from a source area. On a reflective surface of the collector, there is mounted a diffraction grating for the EUV used light. The EUV used light which emanates from the source area is diffracted by the diffraction grating toward a collection area. The reflective surface is designed at least partly as a planar reflective surface, as a parabolic reflective surface, as a rotationally symmetrically frustoconical reflective surface, or as a hollow-cylindrical reflective surface. A design of the reflective surface with ellipsoid reflective surface portions with first focal points, which lie in the source area, and second focal points, which are at a distance from one another and from the collection area, is also possible.

### CROSS-REFERENCE TO RELATED APPLICATIONS

The present application is a continuation of, and claims benefit under 35 USC 120 to, international application No. PCT/EP2023/085374, filed Dec. 12, 2023, which claims benefit under 35 USC 119 of German Application No. 10 2022 213 822.8, filed Dec. 19, 2022. The entire disclosure of each of these applications is incorporated by reference herein.

### FIELD

The disclosure relates to an EUV collector. Furthermore, the disclosure relates to a source-collector module with such an EUV collector, to an illumination optical unit for an EUV projection exposure apparatus with such an EUV collector, to a projection exposure apparatus with such an illumination optical unit, to a method for producing a microstructured or nanostructured component with the aid of such a projection exposure apparatus and to a component produced using such a method.

### BACKGROUND

An EUV collector is known from, for example, WO 2022/002 566 A1, U.S. Pat. No. 9,541,685 B2, U.S. Pat. No. 7,084,412 B2 and DE 10 2017 204 312 A1. Design variants of an EUV collector are known from, for example, U.S. Pat. No. 9,612,370 B1, DE 10 2013 002 064 A1, DE 10 2010 063 530 A1 and US 2009/0289205 A1.

### SUMMARY

The present disclosure seeks to develop an EUV collector so that an effective separation of EUV used light which is to be collected with the aid of the collector from extraneous light with a wavelength that differs from a used light wavelength is possible with reasonable production expenditure.

In an aspect, the disclosure provides an EUV collector for collecting EUV used light emanating from a source area. The EUV collector comprises a reflective surface which can be aligned with the source area. On the reflective surface, there is mounted a diffraction grating for the EUV used light, designed so that the EUV used light which emanates from the source area is diffracted by the diffraction grating toward a collection area. The reflective surface is designed so that extraneous light with a wavelength that differs from a wavelength of the EUV used light is reflected along an extraneous light beam path into an extraneous light beam of which the beam cross section is greater than twice a diameter of a beam of the EUV used light in the collection area along the extraneous light beam path after reflection of the extraneous light at the reflective surface.

According to the disclosure, it has been recognized that an EUV collector in which the diameter of an extraneous light beam is more than twice as great as the diameter of used light in the collection area can have the effect that a thermal load on components exposed to extraneous light, such as a thermal load on an extraneous light trap, caused by incidence of the extraneous light can be reduced, which can reduce reduces certain demands for such components exposed to extraneous light, such as the presence of the extraneous light trap, as well as, where applicable, thermal effects on components that are adjacent to components exposed to extraneous light, such as thermal effects on components adjacent to the extraneous light trap. The beam cross section of the extraneous light beam is greater than twice a diameter of the beam of the EUV used light in the collection area along the extraneous light beam path after reflection at the reflective surface. The beam cross section of the extraneous light beam may be greater than twice a diameter of the beam of the EUV used light in the collection area along the entire extraneous light beam path after the source area. The beam cross section of the extraneous light beam may be greater than twenty times, than thirty times or than fifty times a diameter of the beam of EUV used light in the collection area at the location of a component exposed to extraneous light in the beam path after the reflection of the extraneous light at the reflective surface, after the source area and for example at the location of the extraneous light trap. It has been recognized for example that it is possible to design the diffraction grating of such an EUV collector so that a diffractive transfer of the EUV used light into the collection area can be ensured largely independently of the form of the reflective surface or of reflective surface portions of the EUV collector. A grating period of the diffraction grating over the reflective surface or the reflective surface portions is then often dependent on the location of the diffraction grating on the reflective surface or on the reflective surface portion. With a given geometry of the arrangement of the source area in relation to the reflective surface and with a given target position for the collection area, this dependence is deterministic and there is correspondingly a solution for this location dependence of the grating period.

The diffraction grating may be designed as a blaze diffraction grating to support the diffraction effect for the EUV used light.

At least one of the reflective surface portions may be designed so that extraneous light which emanates from the source area is reflected back again to the source area after reflection at this reflective surface portion. This can improve an energy efficiency of the EUV radiation source.

The beam cross section of the extraneous light beam can be greater than twice a diameter of a beam of the EUV used light in the collection area along the entire extraneous light beam path between the source area and an extraneous light trap. Such an extraneous light trap may be designed as absorbent and/or reflective and/or scattering.

The reflective surface can be designed at least partly: as a planar reflective surface; as a parabolic reflective surface; as a rotationally symmetrically frustoconical reflective surface; or as a hollow-cylindrical reflective surface. Such an EUV collector can be produced with reasonable expenditure with respect to this reflective surface.

If a design at least partly with a parabolic reflective surface is provided, a parabolic focal point of this parabolic reflective surface may lie in the source area. A paraboloid of a corresponding parabolic reflective surface may have a vertical circle. This vertical circle can define a plane in which the source area is arranged. When using a plasma EUV radiation source, this can help allow multiple guidance of pumped light through the source area, to be specific for example once directly and once after double reflection at the parabolic reflective surface.

Two adjacent reflective surface portions of the EUV collector may merge into one another by way of a transitional edge region. Such a transitional edge region may be realized in the form of an edge, i.e. a discontinuous transition, or in the form of a rounded, i.e. continuous, transition. Alternatively, there may also be gaps between adjacent reflective surface portions, which can be used for example for flushing the reflective surface portions with a flushing or cleaning gas.

The reflective surface can be designed as rotationally symmetrical around an axis of symmetry. Such a rotational symmetry of the reflective surface or a reflective surface portion can allow a reflective surface base body of the collector to be produced by machining. The diffraction grating can then be mounted on this base body.

The reflective surface can have at least two reflective surface portions, which assume a smallest angle in relation to one another that is greater than 7°. Such reflective surface portions can allow the construction of a compact EUV collector. The smallest angle between the reflective surface portions may be 90°, may be 45° or may be 30°. The reflective surface portions may merge seamlessly into one another.

At least one of the reflective surface portions is planar. It is also possible for there to be multiple planar reflective surface portions, and for all the reflective surface portions to be designed as planar.

The reflective surface can have at least two planar reflective surface portions, which assume a smallest angle in relation to one another that is greater than 7°. Such a collector can have corresponding desirable features. The collector may have at least three planar reflective surface portions, which assume a smallest angle in relation to one another that is greater than 7°.

The number of reflective surface portions may also be greater than three. In general, this number is less than 20.

The axis of symmetry can be oriented perpendicularly to the planar reflective surface or to a planar reflective surface portion or in that the axis of symmetry is oriented parallel to the orientation of the reflective surface portion. Such orientations of the axis of symmetry can be adapted to the symmetry of corresponding reflective surface portions.

The planar reflective surface or at least a planar reflective surface portion can be designed as a planar reflective panel with a through opening for pumped light. Such a configuration can be produced with comparatively little expenditure. It is also possible for multiple planar reflective panels to be provided. Each of the reflective panels may have a through opening for the pumped light.

The EUV collector can have at least one hollow circular-cylinder reflective portion, the inner wall of which is used for reflection and for diffraction and has the diffraction grating, and/or the EUV collector can have at least one hollow-cone reflective surface portion, the inner wall of which is used for reflection and for diffraction and has the diffraction grating. Such configurational variants have been found to be particularly suitable, depending on the desired structural properties and the desired reflection and diffraction properties.

With the reflective surface aligned with the source area, the source area can lie at a focal point of the parabolic reflective surface portion and/or at the focal point of at least one of the ellipsoid reflective surface portions. The features of such an arrangement have already been discussed above.

In an aspect, the disclosure provides an EUV collector for collecting EUV used light emanating from a source area. The EUV collector comprises a reflective surface, which can be aligned with the source area. On the reflective surface, there is mounted a diffraction grating for the EUV used light, designed so that the EUV used light which emanates from the source area is diffracted by the diffraction grating toward a collection area. The reflective surface is designed at least partly as: a planar reflective surface; a parabolic reflective surface; a rotationally symmetrically frustoconical reflective surface; or a hollow-cylindrical reflective surface.

According to the disclosure, it has been recognized that an EUV collector with an at least partly planar, parabolic, rotationally symmetrically frustoconical or hollow-cylindrical reflective surface can be produced with reasonable expenditure with respect to this reflective surface. It has been recognized for example that it is possible to design the diffraction grating of such an EUV collector in such a way that a diffractive transfer of the EUV used light into the collection area can be ensured largely independently of the form of the reflective surface or of reflective surface portions of the EUV collector. A grating period of the diffraction grating over the reflective surface or the reflective surface portions is then often dependent on the location of the diffraction grating on the reflective surface or on the reflective surface portion. With a given geometry of the arrangement of the source area in relation to the reflective surface and with a given target position for the collection area, this dependence is deterministic and there is correspondingly a solution for this location dependence of the grating period.

The diffraction grating may be designed as a blaze diffraction grating to support the diffraction effect for the EUV used light. If a design at least partly with a parabolic reflective surface is provided, a parabolic focal point of this parabolic reflective surface may lie in the source area. A paraboloid of a corresponding parabolic reflective surface may have a vertical circle. This vertical circle can define a plane in which the source area is arranged. When using a plasma EUV radiation source, this can help allow multiple guidance of pumped light through the source area, to be specific for example once directly and once after double reflection at the parabolic reflective surface.

In an aspect, the disclosure provides an EUV collector for collecting EUV used light emanating from a source area. The EUV collector comprises a reflective surface, which can be aligned with the source area. On the reflective surface, there is mounted a diffraction grating for the EUV used light, designed so that the EUV used light which emanates from the source area is diffracted by the diffraction grating toward a collection area. The reflective surface has: a first ellipsoid reflective surface portion with a first focal point, which lies in the source area, and a further, second focal point; and a second ellipsoid reflective surface portion with a first focal point, which lies in the source area, and a further, second focal point. The two further focal points of the two ellipsoid reflective surface portions are at a distance from one other and from the collection area.

Alternatively, the EUV collector described in the preceding paragraph may have two ellipsoid reflective surface portions, the one focal point of which in each case lies in the source area and the other focal point of which in each case is arranged at a distance from the collection area, these further focal points also being at a distance from one another. This allows a reflective guidance of extraneous light, such as light emanating from the source area with a wavelength that deviates from the wavelength of the EUV used light, toward the further focal points of the ellipsoid reflective surface portions that are at a distance from the collection area. The ellipsoid reflective surface portions may merge seamlessly into one another by way of a transitional area. In the transitional area, a continuous, i.e. edge-free, transition may be provided.

Two adjacent reflective surface portions of the EUV collector may merge into one another by way of a transitional edge region. Such a transitional edge region may be realized in the form of an edge, i.e. a discontinuous transition, or in the form of a rounded, i.e. continuous, transition. Alternatively, there may also be gaps between adjacent reflective surface portions, which can be used for example for flushing the reflective surface portions with a flushing or cleaning gas.

In an aspect, the disclosure provides a source-collector module with an EUV light source and an EUV collector according to the disclosure.

The desirable features of a source-collector module correspond to those that have already been explained above in connection with the EUV collector. The EUV light source may be a plasma source, which for example has an infrared pump laser. The EUV light source may be a tin-based or xenon-based EUV light source. The diffraction grating of the EUV collector can be designed in such a way that a wavelength range of the pumped light is not diffracted at the diffraction grating. The pumped light is therefore extraneous light that is not to be diffracted by the diffraction grating.

In comparison with collectors in which extraneous light of higher wavelengths is diffracted, the diffraction structures of the diffraction grating of the collector according to the disclosure that diffract the EUV used light can have smaller structure depths, which can lead to shorter etching times in an etching production process. The EUV used light can be separated from the extraneous light so effectively that lithography masks without a protective film, for example without a pellicle, can be used during the projection exposure, which further reduces reflection losses.

In an aspect, the disclosure provides a projection exposure apparatus for EUV projection lithography with an EUV light source and an illumination optical unit according to the disclosure for transferring illumination light from the light source into an object field in which a reticle with structures to be projected as images can be arranged, and with a projection optical unit for projecting an image of the object field into an image field.

In an aspect, the disclosure provides a method for producing a microstructured or nanostructured component, with the following steps: providing a substrate, to which a layer of a light-sensitive material is at least partly applied; providing a reticle, which has structures to be projected as images; and projecting at least part of the reticle onto a region of the light-sensitive layer of the substrate with the aid of the projection exposure apparatus according to the disclosure.

The desirable features of an illumination optical unit according to the disclosure, a projection exposure apparatus according to the disclosure, a production method according to the disclosure for a microstructured or nanostructured component, and a component produced by such a method corrrespond to those that have already been explained above with reference to the EUV collector or the source-collector module. The component produced may be a microchip, such as a memory chip.

According to one embodiment, the EUV collector may be an EUV collector for a mask inspection device and/or for a mask metrology device. A mask inspection system is known, for example, from U.S. Pat. No. 10,042,248 B2, DE 102 20 815 A1 and WO 2012/101 269 A1.

According to one embodiment, the illumination optical unit may be an illumination optical unit for a mask inspection device and/or for a mask metrology device.

In this case, the mask inspection device and/or the mask metrology device for mask inspection and/or mask metrology may comprise an EUV light source, an illumination optical unit and a projection optical unit or imaging optical unit according to one of the exemplary embodiments described here. The projection optical unit or imaging optical unit may in this case project a magnified image from an object plane into an image plane.

### BRIEF DESCRIPTION OF THE DRAWINGS

Exemplary embodiments of the disclosure are described in greater detail below with reference to the drawing, in which:

FIG. 1 schematically shows a projection exposure apparatus for EUV projection lithography in a meridional section;

FIG. 2 shows a design of a collector of the projection exposure apparatus in a meridional section, beam paths of EUV used light on the one hand and of extraneous light on the other being indicated in each case by a single ray;

FIGS. 3-7 show further designs of a collector of the projection exposure apparatus in each case in a meridional section;

FIG. 8 perspectively shows a further design of a collector of the projection exposure apparatus;

FIGS. 9-11 show further designs of a collector of the projection exposure apparatus in each case in a meridional section;

FIG. 12 schematically shows parameters which can be used for determining a geometrical arrangement of diffraction structures of a diffraction grating of the respective collector; and

FIGS. 13-16 schematically show a half representation of a further design of a collector of the projection exposure apparatus in each case in a meridional section.

### DETAILED DESCRIPTION

Firstly, the general construction of a microlithographic projection exposure apparatus 1 is described.

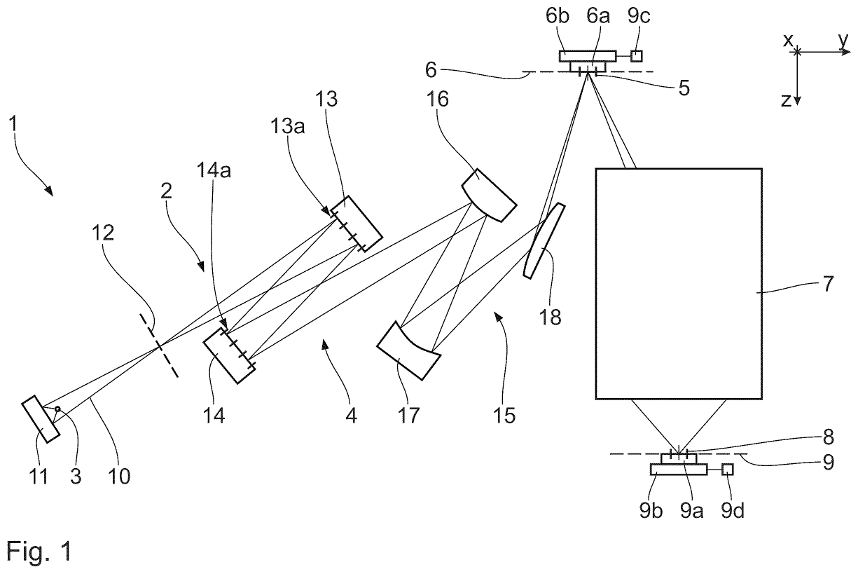

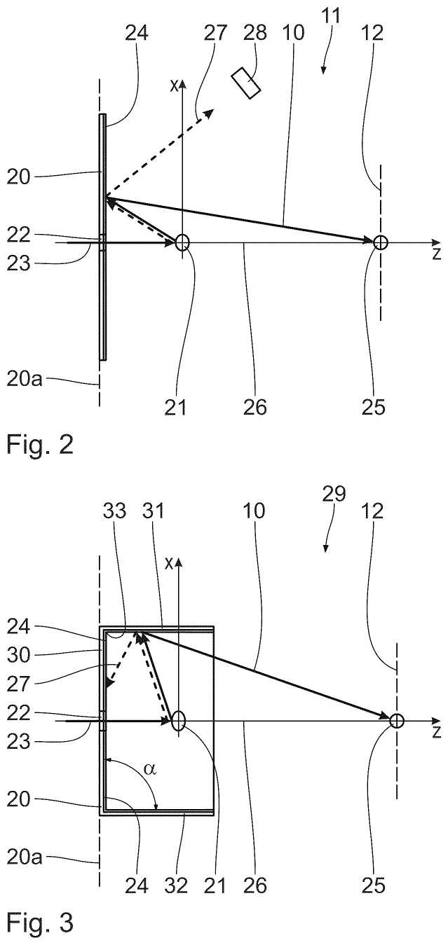

A Cartesian xyz coordinate system is used for the description. In FIG. 1, the x axis is oriented perpendicularly to the plane of the drawing into the latter. The y axis is oriented toward the right. The z axis is oriented downward. In FIG. 2 et seq., a local Cartesian xyz coordinate system, which is arranged in such a way that the x axis of the local coordinate system is oriented parallel to the x axis of the global coordinate system according to FIG. 1 and the x and y axes in each case span a principal plane approximated to a respective optical surface, is used in connection with the description of individual components.

FIG. 1 schematically shows the microlithographic projection exposure apparatus 1 in a meridional section. An illumination system 2 of the projection exposure apparatus 1 has, besides a radiation source 3, an illumination optical unit 4 for the exposure of an object field 5 in an object plane 6. In this case, a reticle 6a which is arranged in the object field 5 and held by a reticle holder 6b is exposed. A projection optical unit 7 is used to project an image of the object field 5 into an image field 8 in an image plane 9. An image of a structure on the reticle is projected onto a light-sensitive layer of a wafer 9a which is arranged in the region of the image field 8 in the image plane 9 and held by a wafer holder 9b.

The reticle holder 6b is driven by a reticle displacement drive 9c and the wafer holder 9b is driven by a wafer displacement drive 9d. The drives provided via the two displacement drives 9c, 9d are performed in a manner synchronized with one another along the y direction.

The radiation source 3 is an EUV radiation source with emitted used radiation in the range of between 5 nm and 30 nm. This may be a plasma source, for example a GDPP (gas discharge-produced plasma) source or an LPP (laser-produced plasma) source. For example, tin may be excited to form a plasma via a carbon dioxide laser operating at a wavelength of 10.6 μm, i.e. in the infrared range. A radiation source based on a synchrotron can also be used for the radiation source 3. A person skilled in the art can find information relating to such a radiation source for example in U.S. Pat. No. 6,859,515 B2.

EUV radiation 10 which emanates from the radiation source 3 is focussed by a collector 11, which is described in more detail below and is only schematically indicated in FIG. 1. Downstream of the collector 11, the EUV radiation 10 propagates through an intermediate focal plane 12 before being incident on a field facet mirror 13 with a multiplicity of field facets 13a. The field facet mirror 13 is arranged in a plane of the illumination optical unit 4 that is optically conjugated with the object plane 6.

The EUV radiation 10 is also referred to hereinafter as illumination light or as imaging light. The EUV radiation 10 that is actually used for the projection exposure in the projection exposure apparatus 1 is also referred to hereinafter as EUV used light. Light or radiation components with a different wavelength than the EUV used light 10 are also referred to hereinafter as extraneous light. A used light wavelength may be 13.5 nm.

After the field facet mirror 13, the EUV radiation 10 is reflected by a pupil facet mirror 14 with a multiplicity of pupil facets 14a. The pupil facet mirror 14 is arranged in a pupil plane of the illumination optical unit 4 that is optically conjugated with a pupil plane of the projection optical unit 7. With the aid of the pupil facet mirror 14 and an imaging optical assembly in the form of a transfer optical unit 15 with mirrors 16, 17 and 18 for guiding the EUV radiation 10, which are designated according to their order in the beam path, images of the field facets 13a of the field facet mirror 13 are projected into the object field 5 while being superposed on one another. The last mirror 18 of the transfer optical unit 15 is a grazing incidence (GI) mirror. Depending on the design of the illumination optical unit 4, the transfer optical unit 15 can also be dispensed with entirely or partially.

FIG. 2 in turn shows a design of the collector 11 in a meridional section. The collector 11 has a reflective surface 20, which is aligned with a source area 21 of the radiation source 3 from which radiation, including the EUV radiation 10, emanates. The reflective surface 20 is designed overall as a planar, flat reflective surface. The reflective surface 20 has a through opening 22 for pumped light 23 to pass through for generating the plasma in the source area 21. The pumped light 23 may have a pumped light wavelength in the infrared wavelength range, for example in the range of 10.6 um.

The reflective surface 20 is designed as a planar reflective panel. On the reflective surface 20 there is mounted a diffraction grating 24 for the EUV used light 10. The diffraction grating 24 is designed in such a way that the EUV used light 10 which emanates from the source area 21 is diffracted by the diffraction grating 24 toward a collection area 25. The collection area 25 lies in the intermediate focal plane 12. The reflective surface 20 may extend parallel to the intermediate focal plane 12.

The reflective surface 20 with the diffraction grating 24 may be designed in the manner of a Fresnel mirror.

A connecting line 26 between centers of the source area 21 and the collection area 25 is perpendicular to an arrangement plane of the reflective surface 20. The pumped light 23 is radiated through the through opening 22 along this connecting line 26 into the source area 21.

The reflective surface 20 may be designed as symmetrical around the connecting line 26, which then represents an axis of symmetry of the reflective surface 20 and also of the entire collector 11.

The connecting line 26 may be the optical axis of the collector 11.

The diffraction grating 24 is structured, e.g. blazed, in such a way that a reflection at diffraction structures of the diffraction grating 24 supports the diffraction of the EUV used light in the direction of the collection area 25.

Light or radiation components 27 which emanate from the source area 21 with a different wavelength than a used light wavelength of the EUV used light 10 and are also referred to as extraneous light are not diffracted by the reflective surface 20 of the collector 11, but reflected according to the extent of the planar arrangement plane of the reflective surface 20. This is illustrated in FIG. 2 by the example of a single ray of the extraneous light 27.

A wavelength difference between a wavelength AN of the EUV used light 10 and a wavelength AF of the extraneous light 27 satisfies the following relation:

$$\frac{{( {λ}_{N} - {λ}_{F} )}^{2}}{{( {λ}_{N} + {λ}_{F} )}^{2}} > 5 \%$$

This wavelength difference (left side of the above relation) may be greater than 10%, may be greater than 20%, may be greater than 25%, may be greater than 30%, may be greater than 40%, may be greater than 50%, may be greater than 90%, may be greater than 95% and may be greater than 99%.

An angle of incidence of the extraneous light 27 on the arrangement plane 20a of the reflective surface 20 is equal to an angle of reflection of the extraneous light 27 reflected by the reflective surface 20.

The collector 11 according to FIG. 2 results in a good spatial separation between the EUV used light 10 and the extraneous light 27.

The extraneous light 27 reflected by the reflective surface 20 can then be removed to an extraneous light trap 28, which in FIG. 2 is schematically shown for the illustrated single ray of the extraneous light 27. The reflective surface 20 is in this case designed in such a way that it reflects the extraneous light 27 along an extraneous light beam path into an extraneous light beam of which the beam cross section is greater than twice a diameter of a beam of the EUV used light 10 in the collection area 25 along the entire extraneous light beam path between the source area 21 and an extraneous light trap. This is explained in still more detail below in connection with some exemplary embodiments.

FIG. 3 shows a further design of a collector 29, which can be used in the projection exposure apparatus 1 instead of the collector 11. Components and functions corresponding to those which have been explained above with reference to the collector 11 according to FIGS. 1 and 2 bear the same reference signs and are not discussed in detail again.

The collector 29 has two reflective surface portions 30, 31.

The reflective surface portion 30 of the collector 29 is in turn designed as a planar reflective panel of the same type as the reflective surface 20 of the collector 11. The reflective surface portion 30 in turn has a through opening 22 for the pumped light 23.

The reflective surface portion 30 is adjoined by the further reflective surface portion 31 of the collector 29, which is designed as a hollow circular-cylinder reflective surface portion, the inner wall 32 of which is used for diffraction and for reflection.

Both the reflective surface portion 30 and the reflective surface portion 31 in turn bear diffraction gratings 24 for diffraction of the EUV used light 10, as already explained above with reference to the design according to FIG. 2.

FIG. 3 in turn illustrates the beam paths of single rays on the one hand of the EUV used light 10, which in turn is diffracted from the source area 21 toward the collection area 25, and of the extraneous light 27, which is reflected by the reflective surface portions 31, 30, diffraction structures of the diffraction grating 24 remaining ineffective. The extraneous light 27 may in this case be reflected a number of times by the reflective surface portions 30, 31, as indicated in FIG. 3. Where the extraneous light 27 leaves a beam path of the EUV used light 10 in the region of the collector 29, an extraneous light trap of the same type as the extraneous light trap 28 may in turn be arranged.

In the meridional section according to FIG. 3, the reflective portions 30, 31 in each case assume a smallest angle a of 90° in relation to one another in a transitional area 33.

The connecting line 26 represents an axis of rotational symmetry for the hollow circular-cylinder reflective surface portion 31.

The source area 21 lies within the volume taken up by the hollow circular-cylinder reflective surface portion 31.

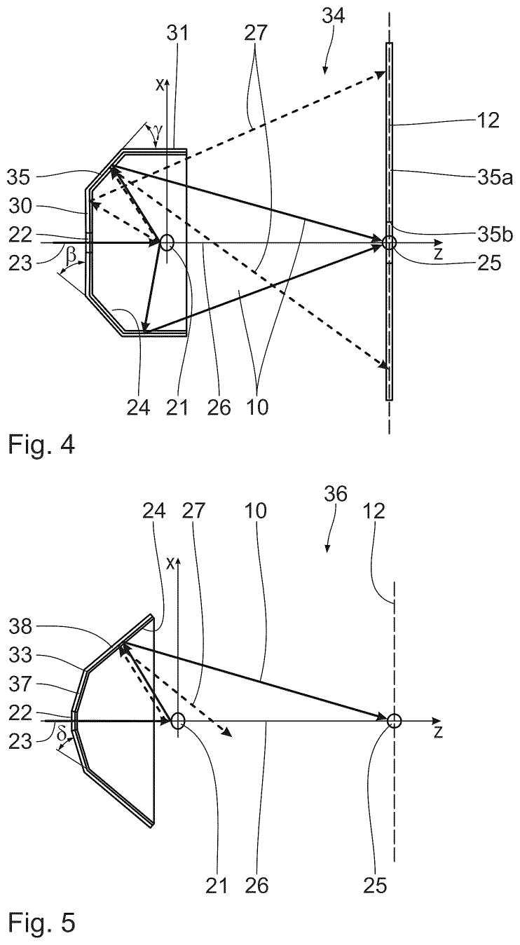

FIG. 4 shows a further design of a collector 34, which can be used in the projection exposure apparatus 1 instead of the collector 11. Components and functions corresponding to those which have been explained above with reference to FIGS. 1 to 3 bear the same reference signs and are not discussed in detail again.

In addition to the planar reflective surface portion 30 and the hollow circular-cylinder reflective surface portion 31 of the same type as the collector 29, the collector 34 has in the transitional area 33 a rotationally symmetrically frustoconical reflective surface portion 35, which is also referred to as a hollow-cone reflective surface portion. Also in the case of the hollow-cone reflective surface portion 35, its inner wall is used for diffraction and for reflection. Also, the hollow-cone reflective surface portion 35 has on the inside the diffraction grating 24 for diffraction of the EUV used light 10 and is used reflectively for the extraneous light 27, the diffraction grating 24 then remaining ineffective. This effect of the hollow-cone reflective surface portion 35 is in turn illustrated in FIG. 4 in each case via two single rays, on the one hand of the EUV used light 10 and on the other hand of the extraneous light 27.

The reflective surface portions 30, 31 and 35 of the collector 34 reflect the extraneous light 27 along an extraneous light beam path into an extraneous light beam of which the beam cross section in the intermediate focal plane 12 is indicated by the extent of a surface of an extraneous light trap 35a. The beam cross section of the beam of the extraneous light 27 is greater than twice a diameter of a beam of the EUV used light 10 in the collection area 25 along the entire extraneous light beam path between the source area 21 and the extraneous light trap 35a. Thus, the extraneous light 27 can be expanded in the intermediate focal plane 12 in such a way that it is possible there, for example by absorption at the extraneous light trap 35a, for it to be removed well and separated from the used light 10, which passes through a through opening 35b in the extraneous light trap 35a through the latter in the collecting area 25.

In the transitional area 33, the planar reflective surface portion 30 and the hollow-cone reflective surface portion 35 merge into one another by way of a smallest angle β, which is 45°. The hollow-cone reflective surface portion 35 and the circular-cylinder reflective surface portion 31 also merge into one another by way of a smallest angle γ of 45°.

FIG. 5 shows a further design of a collector 36, which can be used in the projection exposure apparatus 1 instead of the collector 11. Components and functions corresponding to those which have been explained above with reference to FIGS. 1 to 4 bear the same reference signs and are not discussed in detail again.

The collector 36 has a reflective surface with a first, inner hollow-cone reflective surface portion 37, which in turn has the through opening 22, and a second, outer hollow-cone reflective surface portion 38, which adjoins the inner reflective surface portion 37 by way of a transitional area 33. A smallest angle 8 between the two inner reflective surface portions 37, 38 in the transitional area 33 is about 30°.

The transitional area 33 may be designed as a transitional edge area. In the transitional area 33 there is a rounded, continuous transition between the reflective surface portions 37, 38 merging into one another by way of the transitional area 33.

The reflective surface portions 37, 38 in turn bear the diffraction grating 24 for diffraction of the EUV used light 10. The extraneous light 27 is reflected by the reflective surface portions 37, 38, without the diffraction grating 24 having an effect in this case.

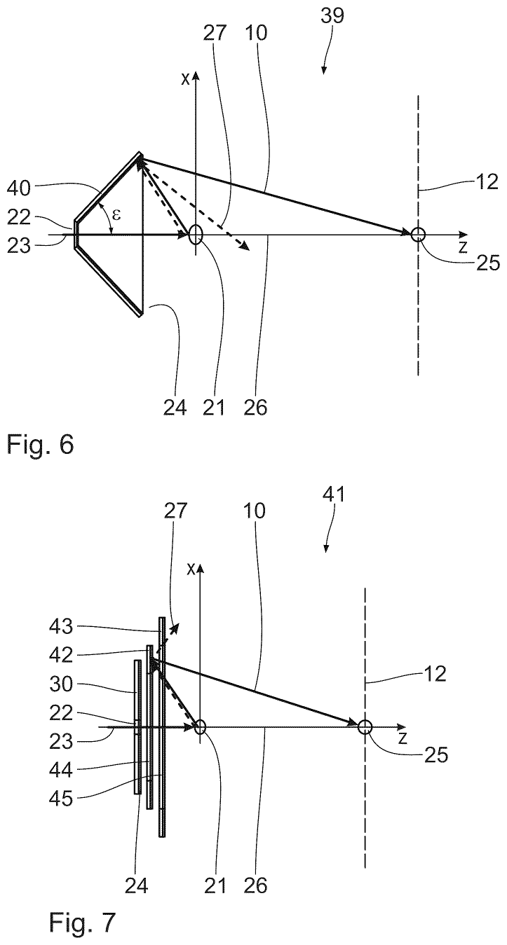

FIG. 6 shows a further design of a collector 39, which can be used in the projection exposure apparatus 1 instead of the collector 11. Components and functions corresponding to those which have been explained above with reference to FIGS. 1 to 5 bear the same reference signs and are not discussed in detail again.

The collector 39 has a hollow-cone reflective surface portion 40, which in the meridional section according to FIG. 6 assumes in relation to the connecting line 26, which in turn represents an axis of rotational symmetry of the reflective surface portion 40, an angle ε of about 45°. The reflective surface portion 40 in turn has a through opening 22 for the pumped light 23.

FIG. 7 shows a further design of a collector 41, which can be used in the projection exposure apparatus 1 instead of the collector 11. Components and functions corresponding to those which have been explained above with reference to FIGS. 1 to 6 bear the same reference signs and are not discussed in detail again.

The collector 41 has in addition to the planar reflective panel 30 of the same type as the reflective panels of the collector designs according to FIGS. 3 and 4 also two further planar reflective panels 42, 43 with a diameter of panel openings 44, 45 increasing in a graduated manner and graduated distances from the reflective panel 30 along the connecting line 26, which in turn represents an axis of rotational symmetry for all three reflective panels 30, 42, 43. Depending on the design of the collector 41, the number of reflective panels may also be two, four or five or may also be even greater. The number of reflective panels is often less than 20.

The reflective panels 30, 42, 43 in turn bear the diffraction grating 24 for diffraction of the EUV used light 10. The extraneous light 27 is reflected at the reflective panels 30, 42, 43, without the diffraction grating 24 having an effect in this case.

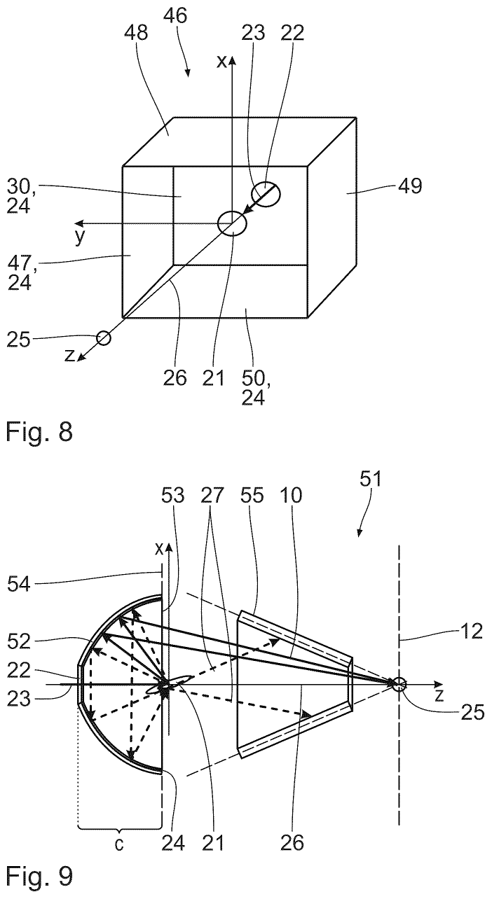

FIG. 8 shows a further design of a collector 46, which can be used in the projection exposure apparatus 1 instead of the collector 11. Components and functions corresponding to those which have been explained above with reference to FIGS. 1 to 7 bear the same reference signs and are not discussed in detail again.

The collector 46 is shown perspectively in FIG. 8, with the viewing direction substantially opposite the direction of a beam of the pumped light 23 through the through opening 22.

In the meridional section, the collector 46 corresponds to the collector 29 according to FIG. 3. Instead of a circular-cylinder reflective surface portion 31 as in the case of the collector 29, the collector 46 has altogher four planar reflective surface portions 47, 48, 49, 50 in addition to the reflective surface portion 30. These altogether five planar reflective surface portions 30 and 47 to 50 result in a box-shaped or cuboidal basic form of the collector 46 with a free opening in the direction of the viewer of FIG. 8.

Inner walls of the reflective surface portions 47 to 50, as well as the reflective surface portion 30, in turn bear the diffraction grating 24 for diffraction of the EUV used light. The EUV extraneous light is reflected at these inner walls, without the respective diffraction grating 24 having an effect in this case.

FIG. 9 shows a further design of a collector 51, which can be used in the projection exposure apparatus 1 instead of the collector 11. Components and functions corresponding to those which have been explained above with reference to FIGS. 1 to 8 bear the same reference signs and are not discussed in detail again.

The collector 51 has a parabolic reflective surface 52 in the form of a paraboloid with a vertical circle 53, in the circle plane 54 of which the source area 21 lies. The connecting line 26 is perpendicular to the circle plane 54.

This paraboloid form of the reflective surface 52 of the collector 51 has the effect that, after two reflections at the parabolic reflective surface 52, pumped light which propagates from the source area 21 in the direction of the reflective surface 52 is reflected back again into the source area 21, which is illustrated in FIG. 9 via two pumped-light or extraneous-light single rays 27. The pumped light 23 thus interacts at least twice with the source area 21, which increases a pumping efficiency of the EUV radiation source 3. Extraneous light 27 not reflected from the source area 21 in the direction of the reflective surface 52 can be removed by a frustoconical extraneous light trap 55. Such an extraneous light trap is described in WO 2022/002 566 A1 (cf. FIG. 2 there).

A course followed by the used light 10 between the source area 21, the reflective surface 52 with a diffracting effect for the used light 10 and the collection area 25 is illustrated in FIG. 9 via two single rays.

The reflective surface 52 is in turn designed in such a way that the extraneous light 27 is reflected along an extraneous light beam path into an extraneous light beam of which the beam cross section is greater than twice the diameter of the beam of the EUV used light 10 in the collection area 25 along the entire extraneous light beam path between the source area 21 and the extraneous light trap 55.

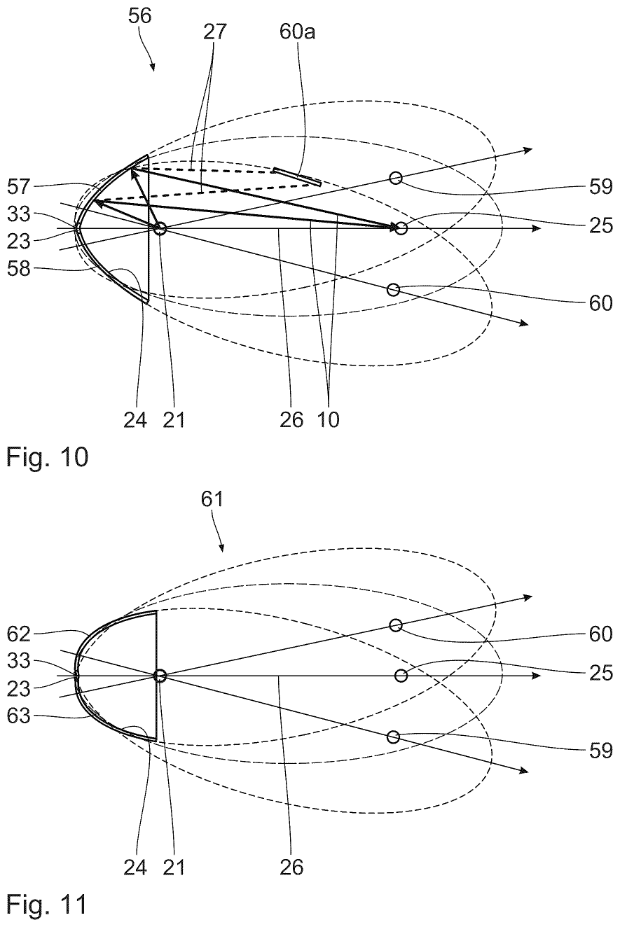

FIG. 10 shows a further design of a collector 56, which can be used in the projection exposure apparatus 1 instead of the collector 11. Components and functions corresponding to those which have been explained above with reference to FIGS. 1 to 9 bear the same reference signs and are not discussed in detail again.

The collector 56 has an ellipsoid reflective surface, which is composed of two ellipsoid reflective surface portions 57, 58. In each case, a first focal point of these two ellipsoid reflective surface portions 57, 58 lies in the source area 21.

A second focal point 59 of the ellipsoid reflective surface portion 57 lies at a distance from the collection area 25 above the connecting line 26 in FIG. 10.

A second focal point 60 of the second ellipsoid reflective surface portion 58 likewise lies at a distance from the collection area 25 below the connecting line 26 in FIG. 10.

With respect to a plane oriented perpendicularly to the plane of the drawing of FIG. 10, in which the connecting line 26 lies, the two second focal points 59, 60 of the ellipsoid reflective surface portions 57, 58 are mirror symmetrical in relation to one another. The collector is rotationally symmetrical with respect to this connecting line 26.

The two ellipsoid reflective surface portions 57, 58 merge into one another by way of a transitional area 33. At the location of this transitional area 33 there may in turn lie a through opening corresponding to the through opening 22 for the pumped light 23 of the embodiments explained above.

A transition angle between the two reflective surface portions 57, 58 in the transitional area 33 is such that the reflective surface of the collector 56 with the two reflective surface portions 57, 58 is designed overall as concave.

The two ellipsoid reflective surface portions 57, 58 in turn bear the diffraction grating 24 for diffraction of the used light 10 emanating from the source area 21 toward the collection area 25, as already explained above in connection with the designs according to FIGS. 2 to 9. This beam path of the used light 10 is illustrated in FIG. 10 via two single rays.

The diffraction grating 24 does not have any effect on the extraneous light, and the extraneous light 27 is removed to the two second focal points 59, 60, depending on whether it has been reflected by the reflective surface portion 57 or 58. These second focal points 59, 60 may in turn be assigned an extraneous light trap, as indicated in FIG. 10 by a portion of an extraneous light trap 60a. A beam path of two selected single rays of the extraneous light 27 between the source area 21 and the extraneous light trap 60a is shown by way of example in FIG. 10. Between the reflective surface portion 57 and the extraneous light trap 60a, these extraneous light single rays 27 are shown by dashed lines. The reflective surface portions 57, 58 are designed in such a way that they reflect the extraneous light 27 along an extraneous light beam path into an extraneous light beam of which the beam cross section is greater than twice a diameter of a beam of the EUV used light 10 in the collection area 25 along the entire extraneous light beam path between the source area 21 and the extraneous light trap 60a.

FIG. 11 shows a further design of a collector 61, which can be used in the projection exposure apparatus 1 instead of the collector 11. Components and functions corresponding to those which have been explained above with reference to FIGS. 1 to 10 and for example with reference to FIG. 10 bear the same reference signs and are not discussed in detail again.

Also, the collector 61 according to FIG. 11 has two ellipsoid reflective surface portions 62, 63 comparable to the collector 56 according to FIG. 10. In the case of the collector 61, the second focal point 59 of the ellipsoid reflective surface portion 62 lies below the connecting line 26 and the second focal point 60 of the further ellipsoid reflective surface portion 63 lies above the connecting line 26.

The ellipsoids which describe the two ellipsoid reflective surface portions 62, 63 on the one hand of the collector 61 and the two reflective surface portions 57, 58 on the other hand of the collector 56 are in each case identical, so have the same lengths of the major axis and minor axis and also the same positions of the focal points.

Due to the reversal of the assignment of the second focal points to the reflective surface portions, a partly convex design of the reflective surface is obtained in the transitional area 33 of the collector 61. In this transitional area 33 there may in turn be arranged a through opening for the pumped light to pass through, as explained above in connection with the designs of FIGS. 1 to 9. Reflective surfaces of the ellipsoid reflective surface portions are rotationally symmetrical around the connecting line 26.

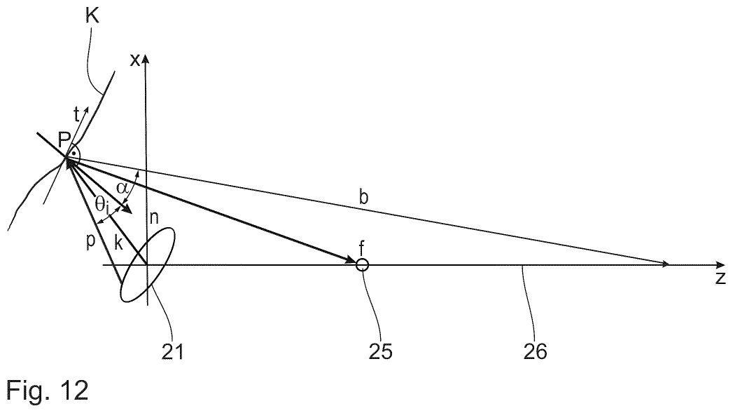

The following considerations can be used to specify the grating structures of the respective diffraction grating 24, using a coordinate system with coordinates x and z, which is illustrated for example in FIGS. 2, 8 and 9. FIG. 12 schematically shows the parameters used in this consideration.

A possible collector reflective surface portion K is assumed to be rotationally symmetrical, continuous and bijective, and can therefore be represented by

$$\vec{k} = ( \begin{matrix}x \\ z\end{matrix} ) = ( \begin{matrix}x \\ k ( x )\end{matrix} ) , \qquad ( 1 )$$

where z is the axis of rotation (cf. FIG. 10). The center of the coordinate system lies at the center of the source area 21. In the z direction, the connecting line 26 or an optical axis of the respective collector is given. A point P on the reflective surface K has a normal direction \vec{n} and a tangential direction \vec{t}

$$\vec{t} = \frac{d}{dx} \vec{k} \vec{n} = ( \begin{matrix}- {t}_{Y} \\ {t}_{x}\end{matrix} ) \qquad ( 2 )$$

A beam emitted or reflected by the plasma is referred to as \vec{p}. The angle of incidence at point P on the collector reflective surface portion K, relative to the normal, is θᵢ. The following holds true:

$$cos {θ}_{i} = \frac{\vec{n} \vec{p}}{\vert \vec{n} \vert \vert \vec{p} \vert} \qquad ( 3 )$$

The diffraction angle α is given in approximation by

$$cos α = \frac{\vec{n} \vec{b}}{\vert \vec{n} \vert \vert \vec{b} \vert} ≃ \frac{\vec{n} ( \vec{f} - \vec{k} )}{\vert \vec{n} \vert \vert \vec{f} - \vec{k} \vert} , \qquad ( 4 )$$

where \vec{f} describes the vector to the center of the collection area 25.

The grating equation is:

$$sin {θ}_{i} - sin α = n \frac{λ}{T} \qquad ( 5 )$$

where α is the diffraction angle, n is the order of diffraction, C is the wavelength of the diffracted EUV used light and T is the location-dependent period. With the aid of the representation sin

$$x = \sqrt{1 - {cos}^{2} x} ,$$

the following is obtained from (5), (3) and (4):

$$\sqrt{1 - {( \frac{\vec{n} \vec{p}}{\vert \vec{n} \vert \vert \vec{p} \vert} )}^{2}} - \sqrt{1 - {( \frac{\vec{n} ( \vec{f} - \vec{k} )}{\vert \vec{n} \vert \vert \vec{f} - \vec{k} \vert} )}^{2}} = n \frac{λ}{T} \qquad ( 6 )$$

Equation (6) combines the specific design parameters of the collector surface, contained in k(x), with the location-dependent periodicity T. This allows the location-dependent period to be calculated, and thus the structure of the diffraction grating 24 to be specified for the respective collector design.

In the case of the planar reflective surface 20 of the collector 11 according to FIG. 2, k(x)=−α applies, where a is the distance between the center of the source area 21, i.e. the coordinate origin, and the reflective surface 20.

In the case of the parabolic collector 51 according to FIG. 9, the collector surface can be written as

$$k ( x ) = \sqrt{\frac{x - c}{a}} .$$

c is in this case a measure of the distance between the center of the source area 21 and a point where the pumped light 23 passes through the reflective surface 52 and a is a measure of a curvature of the reflective surface 52.

In the case of the collectors 56 and 61 according to FIGS. 10 and 11, the reflective surface can be described by the following formula:

$$k ( x ) = d \sqrt{1 - \frac{{x}^{2}}{{a}^{2}}} \qquad ( 7 )$$

a and d in this case each represent a measure of the two ellipsoid semiaxes.

Depending on the design of the collector, the smallest angle that two reflective surface portions of the reflective surface of the collector that merge into each other by way of a transitional area can assume in relation to one another may be greater than 7°.

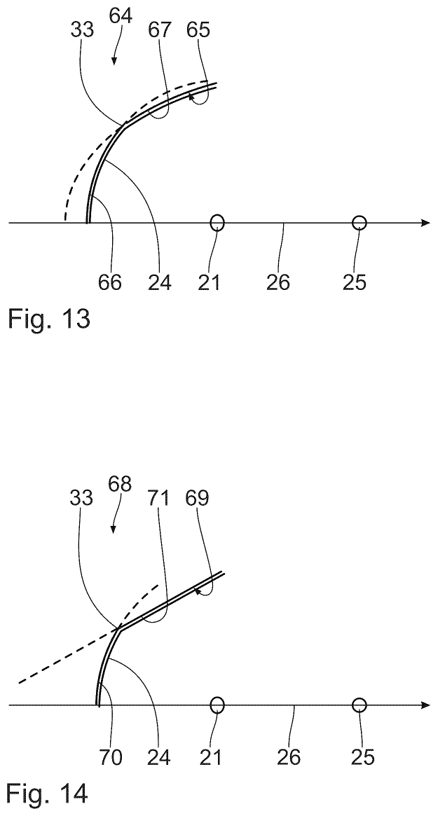

FIG. 13 shows a further design of a collector 64, which can be used in the projection exposure apparatus 1 instead of the collector 11. Components and functions corresponding to those which have already been explained above with reference to FIGS. 1 to 12 bear the same reference signs and are not discussed in detail again.

A reflective surface 65 of the collector 64 is composed of an inner spherical reflective surface portion 66, radially surrounding the connecting line 26 between the source area 21 and the collection area 25, and an outer parabolic reflective surface portion 67 adjoining the inner portion. These two reflective surface portions 66 and 67 are in each case rotationally symmetrical in relation to the connecting line 26. A smallest angle between the two reflective surface portions 66, 67 in the transitional area 33 is about 15°.

FIG. 14 shows a further design of a collector 68, which can be used in the projection exposure apparatus 1 instead of the collector 11. Components and functions corresponding to those which have already been explained above with reference to FIGS. 1 to 13 bear the same reference signs and are not discussed in detail again.

Also in the case of the design according to FIG. 14, a reflective surface 69 of the collector 68 is divided into two reflective surface portions, to be specific into an inner reflective surface portion 70 in a radial region around the connecting line 26 to the transitional area 33, designed as an ellipsoid portion, and a frustoconical reflective surface portion 71 directly adjoining it by way of the transitional area 33. The two reflective surface portions 70 and 71 are in turn rotationally symmetrical around the connecting line 26. A smallest angle between the two reflective surface portions 70, 71 in the transitional area 33 is about 30°.

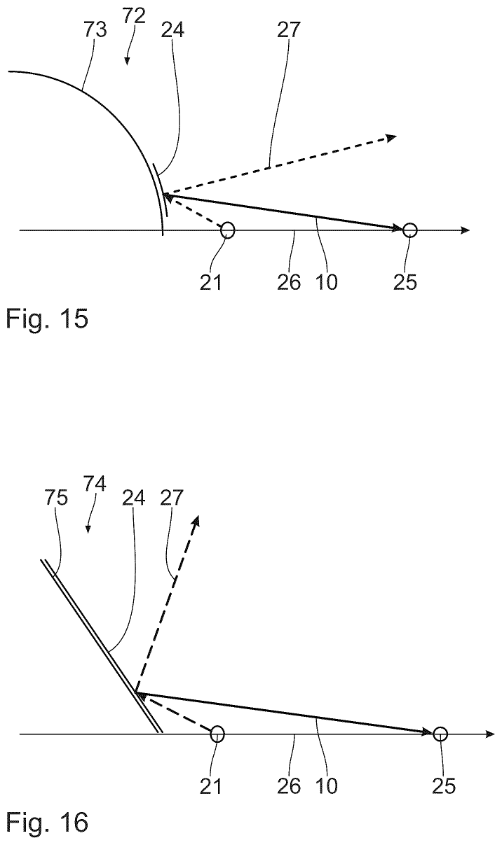

FIG. 15 shows a further design of a collector 72, which can be used in the projection exposure apparatus 1 instead of the collector 11. Components and functions corresponding to those which have already been explained above with reference to FIGS. 1 to 14 bear the same reference signs and are not discussed in detail again.

The collector 72 has a reflective surface 73, which is designed overall as a paraboloid. The reflective surface 73 is rotationally symmetrical around the connecting line 26. The reflective surface 73 on which the diffraction grating 24 is mounted is convex.

FIG. 16 shows a further design of a collector 74, which can be used in the projection exposure apparatus 1 instead of the collector 11. Components and functions corresponding to those which have already been explained above with reference to FIGS. 1 to 15 bear the same reference signs and are not discussed in detail again.

In the case of the collector 74, an entire reflective surface 75 on which the diffraction grating 24 is mounted is designed as a cone surface that is rotationally symmetrical around the connecting line 26. Unlike for example in the case of the frustoconical reflective surface 40, the cone surface is not curved around the source area 21, but in projection onto the connecting line 26 a cone vertex 76 of the reflective surface 75 is closest to the source area 21. Instead of a cone vertex 76, a cone frustum may also be provided in the collector 74. No point on the reflective surface 75 is closer to the source area 21 than an intersection point of the connecting line 26 through the reflective surface 75. In the case of the design of the reflective surface 75 with the cone vertex 76, the cone vertex 76 coincides with this intersection point.

For all of the collector designs 11, 29, 34, 36, 39, 41, 46,51, 64, 68, 72 and 74 explained above it is the case that the reflective surfaces or reflective surface portions there reflect the extraneous light 27 along an extraneous light beam path into an extraneous light beam of which the beam cross section is greater than twice a diameter of a beam of the EUV used light 10 in the collection area 25 along the entire extraneous light beam path after the source area 21. This condition that the beam cross section of the extraneous light beam is greater than twice the diameter of the beam of the EUV used light 10 in the collection area 25 can be satisfied along an entire extraneous light beam path and for example an extraneous light beam path between the source area 21 and a respective extraneous light trap (cf. 35a in FIG. 4, 55 in FIGS. 9 and 60a in FIG. 10).

In general, the relationship between a reflectivity R and an angle of incidence of the EUV used light 10 on the respective reflective surface or on the respective reflective surface portion is considered to be that the reflectivity is highest at small angles of incidence close to normal incidence and decreases toward larger angles of incidence.

The collector designs 29, 34, 36, 56, 61, 64 and 69 explained above are examples of optically structured, composite reflective surfaces in such a way that an EUV used light reflectivity of these reflective surfaces is greater than in the case where only one type of form of a reflective surface is used, i.e. without transitional area 33.

With the aid of the projection exposure apparatus 1, an image of at least part of the reticle in the object field 5 is projected onto a region of a light-sensitive layer on the wafer in the image field 8 for the lithographic production of a microstructured or nanostructured component, such as a semiconductor component, for example a microchip. Depending on the design of the projection exposure apparatus 1 as a scanner or as a stepper, the reticle and the wafer are moved in the y direction in a manner synchronized in time, continuously in scanner operation or step by step in stepper operation.

What is claimed is:

1. An EUV collector, comprising:
a reflective surface; and
a diffraction grating supported by the reflective surface,
wherein:
the diffraction grating is configured so that EUV used light emanating from a source area is diffracted by the diffraction grating to define an EUV used light beam that has an EUV used light beam path that extends to a collection area;
the reflective surface is configured so that extraneous light with a wavelength different from a wavelength of the EUV used light is reflected from the reflective surface to define an extraneous light beam having an extraneous beam path;
the extraneous light beam has a cross section;
the EUV used light beam has a diameter in the collection area;
the cross section of the extraneous light beam is more than twice the diameter of the EUV used light beam in the collection area.

2. The EUV collector of claim 1, further comprising an extraneous light trap, wherein:
the extraneous light beam path extends from the reflective surface to the extraneous light trap; and
along the entire extraneous beam path from the reflective surface to the extraneous light trap, the cross section of the extraneous light beam is greater more than twice the diameter of the EUV used light beam in the collection area.

3. The EUV collector of claim 2, wherein the reflective surface is at least partly:
a planar reflective surface;
a parabolic reflective surface;
a rotationally symmetrically frustoconical reflective surface; or
a hollow-cylindrical reflective surface.

4. The EUV collector of claim 2, wherein the reflective surface is rotationally symmetric around an axis of symmetry.

5. The EUV collector of claim 2, wherein the reflective surface comprises two reflective surface portions, and a smallest angle between the two reflective surface portions is more than 7°.

6. The EUV collector of claim 2, wherein the reflective surface comprises two planar reflective surface portions, and a smallest angle between the two plan reflective surface portions is more than 7°.

7. The EUV collector of claim 1, wherein the reflective surface is at least partly:
a planar reflective surface;
a parabolic reflective surface;
a rotationally symmetrically frustoconical reflective surface; or
a hollow-cylindrical reflective surface.

8. The EUV collector of claim 1, wherein the reflective surface is rotationally symmetric around an axis of symmetry.

9. The EUV collector of claim 1, wherein the reflective surface comprises two reflective surface portions, and a smallest angle between the two reflective surface portions is more than 7°.

10. The EUV collector of claim 1, wherein the reflective surface comprises two planar reflective surface portions, and a smallest angle between the two plan reflective surface portions is more than 7°.

11. The EUV collector as of claim 1, wherein the reflective surface is rotationally symmetric around an axis of symmetry, and wherein:
the reflective surface is planar, and the axis of symmetry is perpendicular to the planar reflective surface; or
the reflective surface comprises a planar reflective surface portion, and the axis of symmetry is perpendicular to the planar reflective surface portion; or
the reflective surface comprises a planar reflective surface portion, the axis of symmetry is parallel to the reflective surface portion.

12. The EUV collector of claim 1, wherein at least a portion of the reflective surface is planar, and at least the portion of the planar portion of the reflective surface comprises a through opening.

13. The EUV collector of claim 1, wherein the reflective surface comprises:
a hollow circular-cylinder reflective portion comprising an inner wall configured to reflect the used EUV light, wherein the diffraction grating is supported by the inner wall; and/or
a hollow-cone reflective surface portion comprising an inner wall configured to reflect the used EUV light, wherein the inner wall supports the diffraction grating.

14. The EUV collector of claim 1, wherein:
the reflective surface comprises a parabolic portion, and, when the reflective surface is aligned with source area, the source area is at a focal point of the parabolic portion of the reflective surface; and/or
the reflective surface comprises an ellipsoidal portion, and, when the reflective surface is aligned with source area, the source area is at a focal point of the ellipsoidal portion of the reflective surface.

15. A source-collector module, comprising:
an EUV light source; and
an EUV collector according to claim 1.

16. An illumination optical unit, comprising:
an EUV collector according to claim 1, wherein the illumination optical unit is an EUV lithography illumination optical unit.

17. An apparatus, comprising:
an EUV light source;
an illumination optical unit comprising an EUV collector according to claim 1, the illumination optical unit configured to transfer illumination light from the light source into an object field; and
a projection optical unit configured to project an image of an object in the object field into an image field of the projection optical unit,
wherein the apparatus is an EUV lithography projection exposure apparatus.

18. A method of using an EUV lithography projection exposure apparatus comprising an illumination optical unit and a projection optical unit, the method comprising:
using the illumination optical unit to illuminate an object in an object field of the projection optical unit; and
using the projection optical unit to project an image of the object into an image field of the projection optical unit,
wherein the illumination optical unit comprises an EUV collector according to claim 1.

19. An EUV collector, comprising:
a reflective surface; and
a diffraction grating supported by the reflective surface,
wherein:
the diffraction grating is configured so that EUV used light emanating from a source area is diffracted by the diffraction grating to define an EUV used light beam that has an EUV used light beam path that extends to a collection area; and
the reflective surface is at least partly:
a planar reflective surface;
a parabolic reflective surface;
a rotationally symmetrically frustoconical reflective surface; or
a hollow-cylindrical reflective surface.

20. An EUV collector, comprising:
a reflective surface; and
a diffraction grating supported by the reflective surface,
wherein:
the diffraction grating is configured so that EUV used light emanating from a source area is diffracted by the diffraction grating to define an EUV used light beam that has an EUV used light beam path that extends to a collection area;
the reflective surface comprises:
a first ellipsoid reflective surface portion having first and second focal points, the first focal point being in the source area; and
a second ellipsoid reflective surface portion having first and second focal points, the first focal point being in the source area; and
the second focal point of the first and second ellipsoidal surface are at a distance from one other and from the collection area.
